(19) United States
(12) Patent Application Publication
(10) Pub. No.: US 2020/0092985 A1
(43) Pub. Date: Mar. 19, 2020

(54) MULTILAYER FILTER PRINTED CIRCUIT BOARD

(71) Applicant: D-WAVE SYSTEMS INC., Burnaby (CA)

(72) Inventors: David S. Bruce, Burnaby (CA); Pedro A. de Buen, Coquitlam (CA)

(21) Appl. No.: 16/562,984

(22) Filed: Sep. 6, 2019

Related U.S. Application Data
(60) Provisional application No. 62/733,184, filed on Sep. 19, 2018.

(51) Int. Cl. H05K 1/02; H05K 3/46

(52) U.S. Cl. CPC H05K 1/0216; H05K 3/4644

(57) ABSTRACT

A multilayer filter printed circuit board includes filtering material in one or more filter layers. The filtering material can include superconducting material, normal material, magnetic material and semi-conductor material. The multilayer filter printed circuit board may be used as part of a tubular filter structure. The filtering material may be dispersed in, or on the filter layers in a pattern or at random. The filter layers may have a first and second portion that are co-planar, and comprising different filtering materials from one another. The first and second portion may be electrically isolated from one another. Two or more filter layers may comprise different filtering materials from one another. Additional filter layers comprising filtering material may be formed outward of the outer electrically insulative layers.

### FIELD

This disclosure generally relates to printed circuit boards and electrical signal filtering.

### BACKGROUND

### Electrical Signal Filtering

During transmission, an electrical signal typically comprises a plurality of components each transmitting at a different frequency. The “filtering” of an electrical signal typically involves the selective removal of certain frequencies from the electrical signal during transmission. Such filtering may be accomplished “passively” or “actively.” A passive electrical filter is one that operates without additional power input; that is, the filtering is accomplished by the natural characteristics of the materials or devices through which the electrical signal is transmitted. Passive filters include filters that implement lumped elements such as inductors and capacitors, collectively referred to as lumped element filters (LEFs).

### Metal Powder Filters

A metal powder filter is a form of high frequency dissipation filter. In its most general form, the metal powder filter employs a hollow conductive housing having an inner volume that is filled with a mixture of metal powder and dielectric. A portion of a conducting wire extends through the inner volume of the housing such that the portion of the conducting wire is completely immersed in the metal powder dielectric mixture. The particles of the metal powder provide a very large surface area over which high frequency signals carried on the conducting wire are dissipated via skin-effect damping associated with the induction of eddy currents in the surrounding metal powder.

Metal powder filters have particular utility in superconducting applications, such as in an input/output system providing electrical communication to/from a superconducting computer processor. For example, a multi-metal powder filter assembly is employed for this purpose in U.S. Pat. No. 8,441,329. In another example, the inner conducting wire is replaced by a printed circuit board (PCB) carrying conductive traces and lumped elements such as capacitors, inductors, and/or resistors. Versions of this design that employ single-ended signaling are described in U.S. Pat. No. 8,008,991, while other versions of this design that are adapted to employ differential signaling are described in U.S. Pat. No. 8,279,022.

The foregoing examples of the related art and limitations related thereto are intended to be illustrative and not exclusive. Other limitations of the related art will become apparent to those of skill in the art upon a reading of the specification and a study of the drawings.

### BRIEF SUMMARY

A multilayer printed circuit board may be summarized as including a first electrically insulative layer, a second electrically insulative layer, and a first filter layer sandwiched between the first and the second electrically insulative layers, the first filter layer having a first electrically conductive filter material dispersed therein and, or thereon. The first electrically conductive filter material may comprise one of: a superconductive material, a normal metal, a superconductive material and a normal material, a ground plane, a magnetic material and a semiconductor material. The superconductive material may be superconductive powder. At least one of the first electrically insulative layers and the second electrically insulative layers may be an FR4 layer. The multilayer printed circuit board may comprise ground planes. The first filter layer may comprise a first portion and a second portion wherein the first and second portions are wherein the first and second portions are co-planar with the first filter layer and wherein the first portion contains the first electrically conductive filter material dispersed therein and, or thereon, and the second portion contains a second electrically conductive filter material dispersed therein and, or thereon. The first electrically conductive filter material and the second electrically conductive filter material may be randomly distributed on the first filter layer. The first electrically conductive filter material and the second electrically conductive filter material may be distributed in a pattern on the first filter layer. The first and second electrically conductive filter material may be electrically coupled together. The first and second electrically conductive filter material may be electrically isolated from each other. The multilayer printed circuit board may comprise a second filter layer sandwiched between the first filter layer and the second electrically insulative later, the second filter layer comprising a second electrically conductive filter material dispersed therein and, or thereon. The printed circuit board may comprise a second filter layer and a third filter layer, wherein the first electrically insulative layer is sandwiched between the first filter layer and the second filter layer and the second insulative layer is sandwiched between the first filter layer and the third filter layer, and the second filter layer contains a second electrically conductive filter material dispersed therein and, or thereon and the third filter layer contains a third electrically conductive filter material dispersed therein and, or thereon. The first electrically conductive filter material may be the same as the second and the third electrically conductive filter material. A method for assembling a multilayer printed circuit board comprises forming a first electrically insulative layer; forming a second electrically insulative layer; forming a first filter layer having a first electrically conductive filter material dispersed therein and, or thereon; and bonding the first filter layer between the first and the second electrically insulative layers. The first filter layer may have one of: a superconductive material, a normal metal, a superconductive material and a normal material, a ground plane, a magnetic material and a semiconductor material, dispersed therein and, or thereon. The first filter layer may have a superconducting metal powder dispersed therein and, or thereon. The first electrically insulative layer may be an FR4 layer and the second electrically insulative layer may be an FR4 layer. Forming a first filter layer may include forming a first portion and a second portion, the first and second portions co-planar with the first filter layer, the first portion containing the first electrically conductive filter material dispersed therein and, or thereon, and the second portion containing a second electrically conductive filter material dispersed therein and, or thereon. The first and second portion may be distributed randomly on the first filter layer. The first and second portion may be distributed in a pattern on the first filter layer. The first and second electrically conductive material may be electrically coupled together. The first and second electrically conductive material may be electrically isolated. The method may include forming a second filter layer sandwiched between the first filter layer and the second electrically insulative layer, the second filter layer comprising a second electrically conductive filter material dispersed therein and, or thereon. The method may include forming a second filter layer and a third filter layer, the first electrically insulative layer sandwiched between the first filter layer and the second filter layer and the second electrically insulative layer sandwiched between the first filter layer and the third filter layer, the second filter layer comprising a second electrically conductive filter material dispersed therein and, or thereon and the third filter layer comprising a third electrically conductive filter material dispersed therein and, or thereon. The second electrically conductive filter material may be the same as the third and the first electrically conductive filter material.

### BRIEF DESCRIPTION OF THE SEVERAL VIEWS OF THE DRAWING(S)

In the drawings, identical reference numbers identify similar elements or acts. The sizes and relative positions of elements in the drawings are not necessarily drawn to scale. For example, the shapes of various elements and angles are not necessarily drawn to scale, and some of these elements may be arbitrarily enlarged and positioned to improve drawing legibility. Further, the particular shapes of the elements as drawn, are not necessarily intended to convey any information regarding the actual shape of the particular elements, and may have been solely selected for ease of recognition in the drawings.

FIG. 1 is an isometric view of an example implementation of a multilayer filter printed circuit board with at least three layers, according to the present disclosure.

FIG. 2 is an isometric view of an example implementation of a multilayer filter printed circuit board with at least five layers, according to the present disclosure.

FIG. 3A is an isometric view of an example implementation of a multilayer filter printed circuit board with at least four layers, according to the present disclosure.

FIG. 3B is a cross-sectional view of the multilayer filter printed circuit board of FIG. 3A.

FIG. 4A is an isometric view of an example implementation of a multilayer filter printed circuit board with at least three layers, including a layer with at least two distinct portions that are co-planar with one another, according to the present disclosure.

FIG. 4B is a cross-sectional view of the multilayer filter printed circuit board of FIG. 4A.

FIG. 5 is a cross-sectional view showing an alignment of a multilayer filter printed circuit board inside a tubular filter structure, according to the present disclosure.

FIG. 6A is a planar view of an exemplary inner layer in a multilayer printed circuit board where filtering material is disposed in a pattern.

FIG. 6B is a planar view of an exemplary inner layer in a multilayer printed circuit board where filtering material is disposed randomly.

FIG. 6C is a planar view of an exemplary inner layer in a multilayer printed circuit board where filtering material comprises a plurality of electrical pathways that are electrically isolated from each other.

FIG. 6D is a planar view of an exemplary inner layer in a multilayer printed circuit board where filtering material comprises an electrical pathway where lengths of electrical wire are electrically connected to each other.

FIG. 7 is a flow chart of an exemplary method for assembling a multilayer filter printed circuit board, according to the present disclosure.

### DETAILED DESCRIPTION

In the following description, certain specific details are set forth in order to provide a thorough understanding of various disclosed implementations. However, one skilled in the relevant art will recognize that implementations may be practiced without one or more of these specific details, or with other methods, components, materials, etc. In other instances, well-known structures associated with printed circuit board technology or printed circuit board materials have not been shown or described in detail to avoid unnecessarily obscuring descriptions of the implementations.

Unless the context requires otherwise, throughout the specification and claims that follow, the word “comprising” is synonymous with “including,” and is inclusive or open-ended (i.e., does not exclude additional, unrecited elements or method acts).

Reference throughout this specification to “one implementation” or “an implementation” or “one embodiment” or “an embodiment” means that a particular feature, structure or characteristic described in connection with the implementation or embodiment is included in at least one implementation or at least one embodiment. Thus, the appearances of the phrases “in one implementation” or “in an implementation” or “one embodiment” or “an embodiment” in various places throughout this specification are not necessarily all referring to the same implementation or the same embodiment. Furthermore, the particular features, structures, or characteristics may be combined in any suitable manner in one or more implementations or one or more embodiments.

As used in this specification and the appended claims, the singular forms “a,” “an,” and “the” include plural referents unless the context clearly dictates otherwise. It should also be noted that the term “or” is generally employed in its sense including “and/or” unless the context clearly dictates otherwise.

The headings and Abstract of the Disclosure provided herein are for convenience only and do not interpret the scope or meaning of the implementations.

Throughout this specification and the appended claims, the term “printed circuit board” includes, but is not limited to, rigid printed circuit boards, flexible printed circuit boards, non-superconducting printed circuit boards, superconducting printed circuit board technology and a combination of the above.

Throughout this specification and the appended claims, the term ‘normal material’ includes, but is not limited to, a non-superconducting material.

The present systems, methods and apparatus describe techniques for additional filtering of electrical signaling using a volume inside a printed circuit board (PCB). Many devices exist for providing passive filtering, including lumped elements and metal powder filters. The implementations described herein provide passive electrical filtering that may be used in combination with other filtering devices, for example as part of a tubular filter structure containing a combination of lumped elements and metal powder. In applications where it is desirable to remove frequencies in the microwave range, a tubular differential filter structure may include one or more structures that cause high frequency attenuation, such as increased length of wire with resistive cladding and/or a metal powder dielectric mixture to realize a metal powder filter. The principles governing the operation of typical metal powder filters are described in F. P. Milliken et al., 2007, Review of Scientific Instruments 78, 024701, U.S. Pat. Nos. 8,441,329 and 8,279,022.

Metal powder filters use metal powder to attenuate high-frequency noise. Such filters may be used in lines where high-frequency noise may perturb and/or distort an electrical signal. For example, metal powder filters may be used on input/output (I/O) lines for classical processors, quantum processors and hybrid processor, where a hybrid processor may be a combination of at least one classical and one quantum processor.

The volume inside a conventional PCB does not contain any metal powder. It may be advantageous if this volume, or part of the volume, were filled with metal powder or a combination of dielectric (e.g., epoxy, FR4, composite PCB material) and metal powder to achieve additional signal filtering. In some implementations, the use of the volume inside the PCB for filtering noise from electrical signals might reduce the number of lumped filter elements and/or reduce the amount of metal powder (or the metal powder/dielectric combination) in tubular filter elements. In some implementations, 20% of the volume inside a tubular filter is occupied by the PCB. Adding metal powder (or metal powder/dielectric combination) could increase the total volume of metal in the tubular filter.

An approach to reduce the volume inside the PCB, thus reducing the amount of volume not used for signal filtering, is to drill out the PCB under some or all the PCB elements, for example under the inductors. When a PCB is used as part of a powder filter, this allows metal powder to seep inside the drilled-out cavities and to occupy at least part of the volume at the core of a filter. However, the drilling weakens the mechanical strength of a PCB. A PCB typically needs to support elements such as inductors, capacitors and resistors and maintain its shape under vibration or other mechanical stress. Weakening the mechanical strength of a PCB might lead to breakage and/or cause the elements installed on a PCB to become detached or damaged.

An alternative approach is to build a PCB with multiple layers to allow filtering material to be formed or deposited into the core of a PCB during the PCB fabrication process. The filtering material could be in one or more additional layers. Positioning filtering material inside the volume of a PCB allows for the filtering material to interact with elements, such as inductors, at a much closer range than, for example, the metal powder on the outer regions of a powder filter.

Examples of multilayer PCBs are described in U.S. Pat. Nos. 8,159,313 and 8,315,678 and International Patent Application No. US2017/65152.

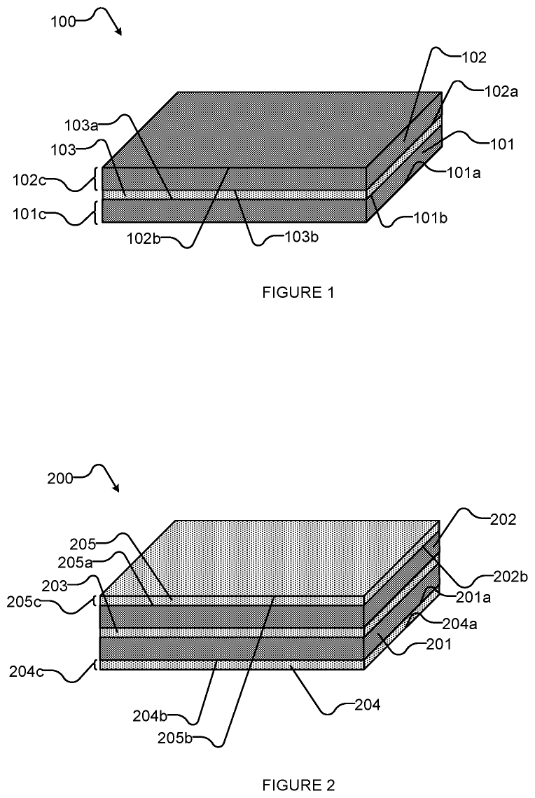

FIG. 1 is an isometric view of a multilayer filter printed circuit board (PCB) 100 with three layers, according to the present system methods and apparatus.

Multilayer filter PCB 100 comprises a first outer layer 101, a second outer layer 102 and an inner layer 103, positioned between first outer layer 101 and second outer layer 102.

First outer layer 101 has a first surface 101a and a second surface 101b, second surface 101b opposed to first surface 101a across a thickness 101c of first outer layer 101. Second outer layer 102 has a respective first surface 102a and a respective second surface 102b, second surface 102b opposed to first surface 102a across a thickness 102c of second outer layer 102. Inner layer 103 has a respective first surface 103a and a respective second surface 103b, second surface 103b opposed to first surface 103a across a thickness of inner layer 103. First surface 103a of inner layer 103 covering at least a portion of second surface 101b of first outer layer 101, second surface 103b of inner layer 103 covering at least a portion of first surface 102a of second outer layer 102, inner layer 103 sandwiched between first outer layer 101 and second outer layer 102.

In some implementations, at least one of first outer layer 101 and second outer layer 102 may be FR4 layers. In some implementations, first outer layer 101 and second outer layer 102 may have different thickness. Inner layer 103 may be deposited or patterned over first outer layer 101 or second outer layer 102 using standard PCB methods, for example photo lithography. Inner layer 103 may be deposited on first outer layer 101 or second outer layer 102 using techniques such as spray coating, electroplating, electro-less plating, evaporation, silkscreen, plasma, sputtering, mechanical spreading, thick-coat, hot or cold rolling, laminating, sintering, molding, casting, and photo lithography.

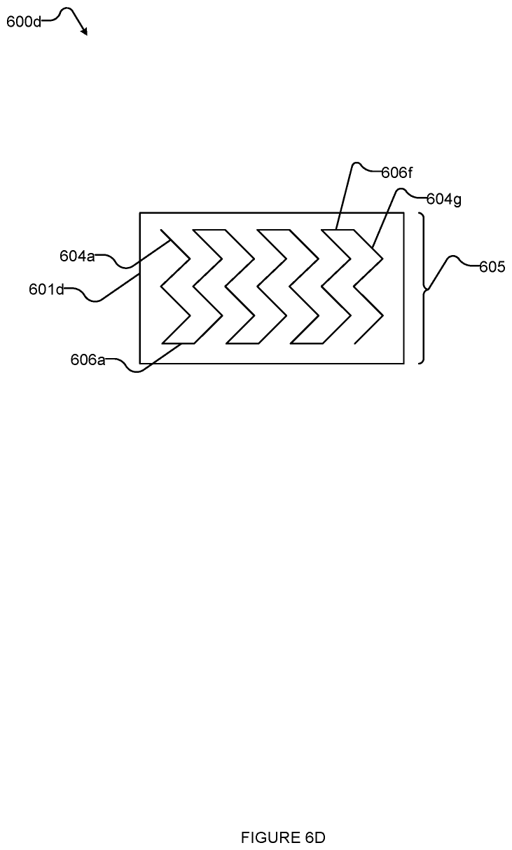

Inner layer 103 comprises filtering material. In the present description and the appended claims, the term ‘filtering material’ is used to denote a material that is electrically conductive. Inner layer 103 may comprise superconducting material, normal material (i.e., a non-superconductive metal), a combination of superconducting and normal material, a ground plane, a magnetic material, or a semi-conductor material. In some implementations, the filtering material may be metal powder as described in more details in U.S. Pat. No. 8,279,022. In some implementations, the filtering material may be metal strands. In some implementations, inner layer 103 may be comprised of filtering material mixed with other dielectric material, for example: varnish, silicone, or polyester. In at least one implementation, inner layer 103 comprises more than one filtering material distributed in a pattern within inner layer 103, as described below with reference to FIGS. 6A, 6B, 6C and 6D. In at least one implementation, the filtering materials are electrically isolated from each other, for example as described below with reference to FIGS. 6B and 6C. In at least one implementation, the filtering materials are electrically connected to each other, for example as described below with reference to FIG. 6D.

In some implementations, it may be desirable to use ground planes to thermalize inner layer 103.

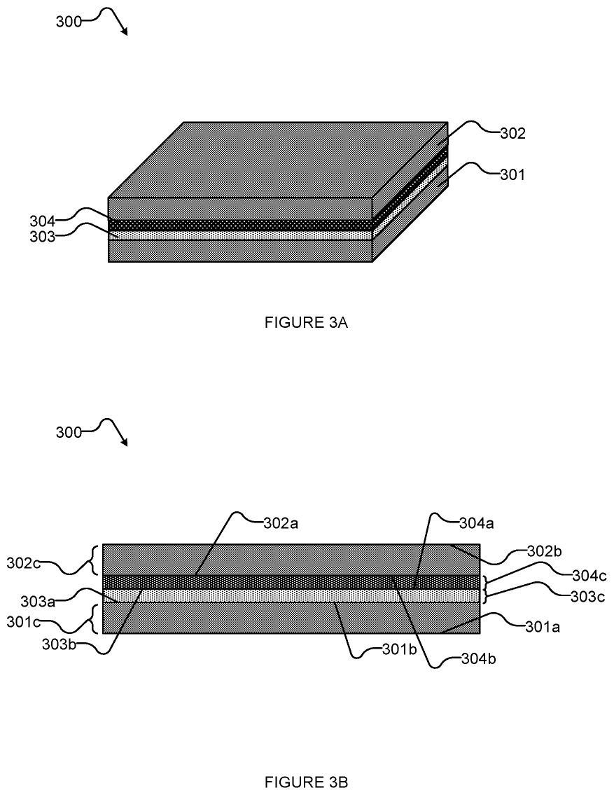

FIG. 2 is an isometric view of a multilayer filter printed circuit board (PCB) 200 with five layers, according to the present system methods and apparatus.

Multilayer filter PCB 200 has a first outer layer 201, a second outer layer 202 and an inner layer 203, similar to first outer layer 101, second outer layer 102 and inner layer 103 of FIG. 1. In particular, inner layer 203 is sandwiched between first outer layer 201 and second outer layer 202.

Multilayer filter PCB 200 has a third layer 204. Third layer 204 has a respective first surface 204a and a respective second surface 204b, second surface 204b of third layer 204 opposed to first surface 204a of third layer 204 across a thickness 204c of third layer 204. Multilayer filter PCB 200 also comprises fourth layer 205. Fourth layer 205 has a respective first surface 205a and a respective second surface 205b, second surface 205b of fourth layer 205 opposed to first surface 205a of fourth layer 205 across a thickness 205c of fourth layer 205. Second surface 204b of third layer 204 at least partially covers a first surface 201a of first outer layer 201 and first surface 205a of fourth layer 205 at least partially covers a second surface 202b of second outer layer 202. Third layer 204 and fourth layer 205 may have different thickness than the thickness of inner layer 203.

Third layer 204 and fourth layer 205 comprise filtering material, as described with reference to inner layer 203. Third layer 204 and fourth layer 205 may comprise superconducting material, normal material, a combination of superconducting and normal material, a ground plane, a magnetic material, or a semi-conductor material. In some implementations, the filtering material may be metal powder. Inner layer 203, third layer 204 and fourth layer 205 may comprise the same filtering material or each contain a respective filtering material that is different from the filtering material in other layers. In some implementations, inner layer 203, third layer 204 and fourth layer 205 may be comprised of filtering material mixed with other dielectric material, for example varnish, silicone or polyester. In at least one implementation, third layer 204 and/or fourth layer 205 comprise more than one filtering material distributed in a pattern, for example as described below with reference to FIGS. 6A, 6B, 6C and 6D. In at least one implementation, the filtering materials are electrically isolated from each other, for example as described below with reference to FIGS. 6B and 6C. In at least one implementation, the filtering materials are electrically connected to each other, for example as described below with reference to FIG. 6D.

In some implementations, it may be desirable to use ground planes to thermalize inner layer 203, third layer 204 and/or fourth layer 205.

One or more of inner layer 203, third layer 204 and fourth layer 205 may be deposited or patterned on first and second outer layers 201 and 202 using techniques such as spray coating, electroplating, electro-less plating, evaporation, silkscreen, plasma, sputtering, mechanical spreading, thick-coat, hot or cold rolling, laminating, sintering, molding, casting and photo lithography.

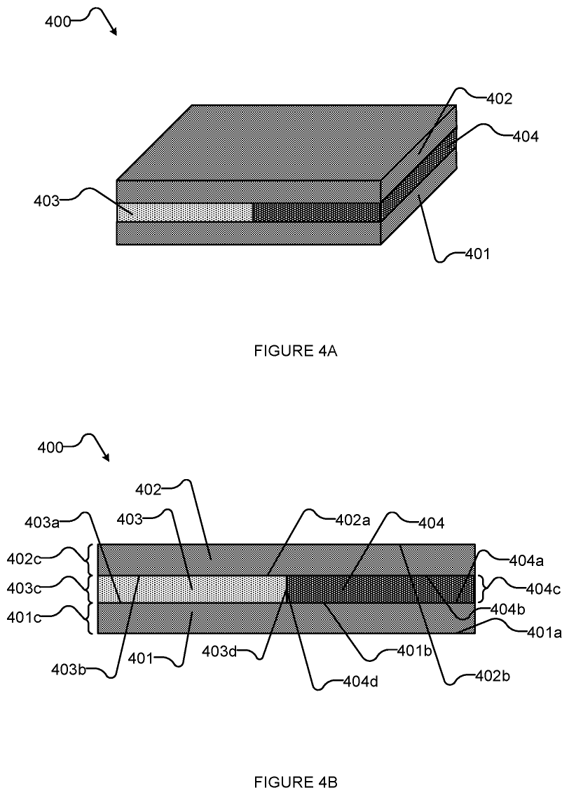

FIG. 3A is an isometric view of an example implementation multilayer filter printed circuit board (PCB) 300 with four layers, according to the present system methods and apparatus.

Multilayer filter PCB 300 comprises a first outer layer 301, a second outer layer 302, a first inner layer 303 and a second inner layer 304. First inner layers 303 and second inner layer 304 are positioned between first outer layer 301 and second outer layer 302.

FIG. 3B is a cross-sectional view of multilayer filter PCB 300 of FIG. 3A showing the relative position of first and second outer layers 301 and 302 and first and second inner layers 303 and 304.

First outer layer 301 has a first surface 301a and a second surface 301b, second surface 301b of first outer layer 301 opposed to first surface 301a first outer layer 301 across a thickness 301c of first outer layer 301. Second outer layer 302 has a first respective surface 302a and a respective second surface 302b, second surface 302b of second outer layer 302 opposed to first surface 302a of second outer layer 302 across a thickness 302c of second outer layer 302. First inner layer 303 has a respective first surface 303a and a respective second surface 303b, second surface 303b of first inner layer 303 opposed to first surface 303a of first inner layer 303 across a thickness 303c of first inner layer 303. Second inner layer 304 has a respective first surface 304a and a respective second surface 304b, second surface 304b of second inner layer 304 opposed to first surface 304a of second inner layer 304 across a thickness 304c of second inner layer 304. First surface 303a of first inner layer 303 at least partially covers second surface 301b of first outer layer 301. Second surface 303b of first inner layer 303 at least partially covers first surface 304a of second inner layer 304. Second surface 304b of second inner layer 304 at least partially covers first surface 302a of second outer layer 302. In other words, at least a portion of first inner layer 303 is sandwiched between at least a portion of first outer layer 301 and at least a portion of second inner layer 304, and at least a portion of second inner layer 304 is sandwiched between at least a portion of second outer layer 302 and first inner layer 303.

In some implementations, at least one of first outer layer 301 and second outer layer 302 may be FR4 layers. In some implementations, first outer layer 301 and second outer layer 302 may have different thickness. First inner layer 303 and second inner layer 304 may be deposited or patterned over first outer layer 301 or second outer layer 302 using standard PCB methods, for example photo lithography. In some implementations, first inner layer 303 and second inner layer 304 may have different thickness.

First inner layer 303 comprises filtering material. First inner layer 303 may comprises superconducting material, normal material, a combination of superconducting and normal material, a ground plane, a magnetic material, or a semi-conductor material. In some implementations, the filtering material may be metal powder or metal strands. Second inner layer 304 comprises filtering material. Second inner layer 304 may superconducting material, normal material, a combination of superconducting and normal material, a ground plane, a magnetic material, or a semi-conductor material. In some implementations, the filtering material may be metal powder. In some implementations, first inner layer 303 and second inner layer 304 may comprise the same material. In some implementations, first inner layer 303 and second inner layer 304 may be comprised of filtering material mixed with other dielectric material, for example varnish, silicone or polyester. In at least one implementation, first inner layer 303 comprises copper and second inner layer 304 comprises tin. First inner layer 303 and second inner layer 304 may be electrically isolated from each other or electrically connected to each other. For example, first inner layer 303 and second inner layer 304 may be electrically connected through vias, plated through holes (PTH), or edge plating (not shown in FIGS. 3A and 3B to reduce clutter).

In at least one implementation, first inner layer 303 and/or second inner layer 304 comprise more than one filtering material distributed in a pattern, for example as described below with reference to FIGS. 6A, 6B, 6C and 6D. In at least one implementation, the filtering materials are electrically isolated from each other within first inner layer 303 and are electrically isolated from each other within second inner layer 304, respectively, as described, for example in FIGS. 6B and 6C. In at least one implementation, the filtering materials are electrically connected to each other within first inner layer 303 and electrically connected to each other within second inner layer 304, respectively, as described, for example, in FIG. 6D.

Multilayer filter PCB 300 may comprise additional inner layers deposited between first outer layers 301 and second outer layer 302 and it may comprise additional layers deposited over second surface 302b of second outer layer 302 and first surface 301a of first outer layer 301. A person skilled in the art will understand that additional combinations of different materials in different layers are possible and the present disclosure is not limited to the description and the appended claims.

One or both of first inner layer 303 and second inner layer 304 may be deposited or patterned on first outer layer 301 or second outer layer 302 using techniques such as spray coating, electroplating, electro-less plating, evaporation, silkscreen, plasma, sputtering, mechanical spreading, thick-coat, hot or cold rolling, laminating, sintering, molding, casting and photolithography.

In some implementations, it may be desirable to use ground planes to thermalize first inner layer 303 and second inner layer 304.

In at least some implementations, a multi-layer PCB starts off with a rigid piece of dielectric (e.g., FR4), and with several separate thin sheets of dielectric with a respective metal pattern on each of at least some of the sheets. These separate sheets are then laminated together as layers to form the multilayer PCB. The filter material can be inserted into the base material of the rigid piece, for example when the rigid piece is fabricated, and, or the filter material can be added in the multiple layers of the thin sheets that are laminated to the rigid PCB. As used herein, the term “pattern” means a geometric pattern (e.g., checkerboard) with repetition in the geometric pattern, a random pattern, or a pathway of electrical wires, conduits or electrically conductive paths.

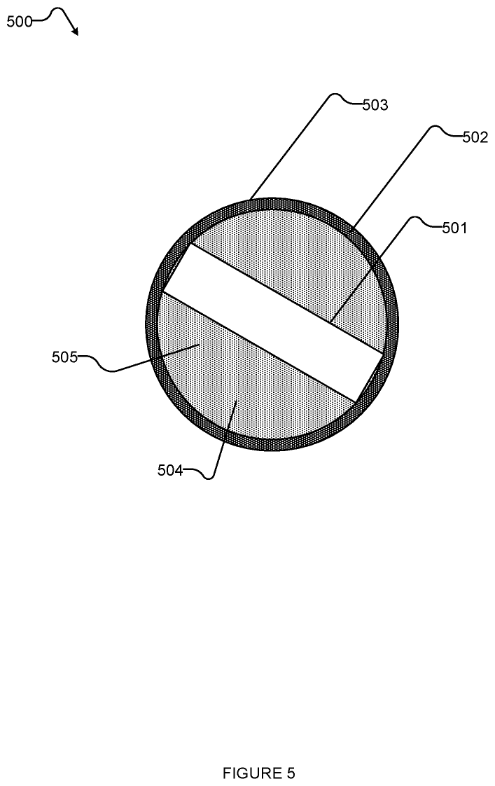

FIG. 4A is an isometric view of an example implementation of a multilayer filter PCB 400 with a plurality of layers, at least one layer comprising two distinct co-planar portions, according to at least one illustrated implementation.

Multilayer filter PCB 400 comprises a first outer layer 401, a second outer layer 402, a first inner layer portion 403 and a second inner layer portion 404 adjacent to first inner layer portion 403. First and second inner layer portions 403 and 404 are positioned between first outer layer 401 and second outer layer 402.

FIG. 4B is a cross-sectional view of multilayer filter PCB 400 of FIG. 4A showing the relative position of first outer layer 401 and second outer layer 402 and first and second inner layer portions 403 and 404.

First outer layer 401 has a first surface 401a and a second surface 401b, second opposite the first surface 401a across a thickness 401c of first outer layer 401. Second outer layer 402 has a respective first surface 402a and a respective second surface 402b, second surface 402b of second outer layer 402 opposed to first surface 402a of second outer layer 402 across a thickness 402c of second outer layer 402.

First inner layer portion 403 has a respective first surface 403a, a respective second surface 403b, second surface 403b of first inner layer portion 403 opposed to first surface 403a of first inner layer portion 403 across a thickness 403c of first inner layer portion 403, and third surface 403d, orthogonal to first surface 403a and second surface 403b. First surface 403a partially covers second surface 401b of first outer layer 401 and second surface 403b partially covers first surface 402a of second outer layer 402.

Second inner layer portion 404 has a respective first surface 404a, a respective second surface 404b, second surface 404b of second inner layer portion 404 opposed to first surface 404a of second inner layer portion 404 across a thickness 404c of second inner layer portion 404, and a respective third surface 404d, orthogonal to first surface 404a and to second surface 404b and adjacent to third surface 403d of first inner layer portion 403. Third surface 403d of first inner layer portion 403 at least partially covers third surface 404d of second inner layer portion 404. First surface 404a partially covers second surface 401b of first outer layer 401 and second surface 404b partially covers first surface 402a of second outer layer 402. In other words, first inner layer portion 403 and second inner layer portion 404 are each sandwiched between first outer layer 401 and second outer layer 402, and are co-planar with one another.

In some implementations, at least one of first outer layer 401 and second outer layer 402 may be FR4 layers. In some implementations, first outer layer 401 and second outer layer 402 may have different thickness. First inner layer portion 403 and second inner layer portion 404 may be deposited or patterned over first outer layer 401 or second outer layer 402 using standard PCB methods, for example photo lithography.

First inner layer portion 403 comprises filtering material. First inner layer portion 403 may comprises superconducting material, normal material, a combination of superconducting and normal material, a ground plane, a magnetic material, or a semi-conductor material. In some implementations, the filtering material may be metal powder or metal strands. Second inner layer portion 404 comprises filtering material. Second inner layer portion 404 may comprise superconducting material, normal material, a combination of superconducting and normal material, a ground plane, a magnetic material, or a semi-conductor material. In some implementations, the filtering material may be metal powder. In some implementations, first inner layer portion 403 and second inner layer portion 404 may comprise the same material. In some implementations, first inner layer portion 403 and second inner layer portion 404 may be comprised of filtering material mixed with other dielectric material, for example varnish, silicone or polyester. First inner layer portion 403 and second inner layer portion 404 may be electrically isolated from each other or may be electrically connected to each other. For example, first inner layer portion 403 and second inner layer portion 404 may be electrically connected to each other through vias, plated through holes (PTH), or edge plating (not shown in FIGS. 4A and 4B to reduce clutter).

In at least one implementation, first inner layer portion 403 and/or second inner layer portion 404 comprise more than one filtering material distributed in a pattern or randomly, as described below with reference to FIGS. 6A, 6B, 6C, and 6D. In at least one implementation, the filtering materials are electrically isolated from each other within first inner layer portion 403 and second inner layer portion 404, for example, as described below with reference to FIGS. 6B and 6C. In at least one implementation, the filtering materials are electrically connected to each other within first inner layer portion 403 and second inner layer portion 404, for example as described below with reference to FIG. 6D.

Multilayer filter PCB 400 may comprise additional inner layers deposited between first outer layer 401 and second outer layer 402 and it may comprise additional layers deposited over second surface 402b of second outer layer 402 and first surface 401a of first outer layer 401. In some implementations, first and second inner layer portions 403 and 404 may be deposited randomly between first outer layer 401 and second outer layer 402. A person skilled in the art will understand that additional combinations of different materials in different layers are possible and the present disclosure is not limited to the description and the appended claims.

One or both of first inner layer portion 403 and second inner layer portion 404 may be deposited on first outer layers 401 or second outer layer 402 using techniques such as spray coating, electroplating, electro-less plating, evaporation, silkscreen, plasma, sputtering, mechanical spreading, thick-coat, hot or cold rolling, laminating, sintering, casting, molding and photo lithography.

In some implementations, it may be desirable to use ground planes to thermalize first inner layer portion 403 and second inner layer portion 404.

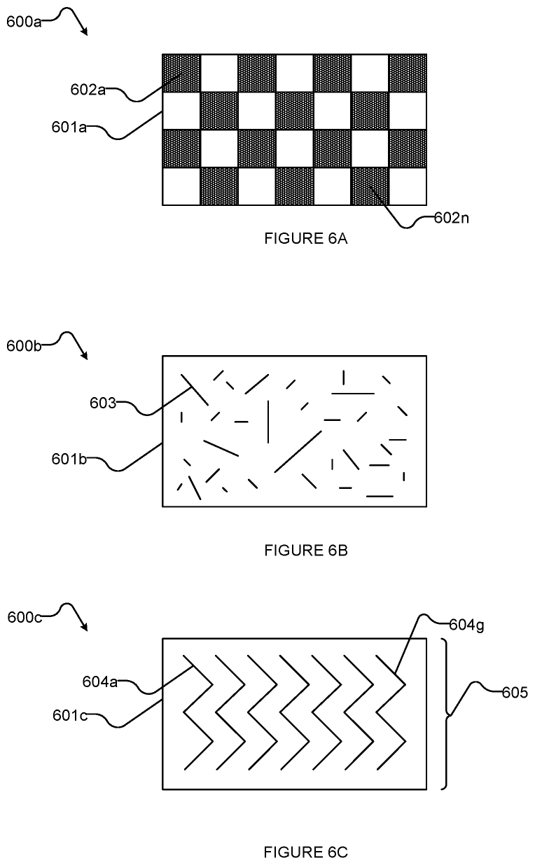

FIG. 5 is a cross-sectional view 500 showing the alignment of a multilayer filter PCB 501 inside a cylindrical body 502 of a tubular filter structure 503, according to the present disclosure.

Tubular filter structure 503 presents a cavity 504, in which PCB 501 is inserted. Cavity 504 of cylindrical body 502 may be filled with a powder 505 (represented by the shading in FIG. 5) to provide electrical filtering. Multilayer filter PCB 501 be implemented as one of multilayer filter PCB 100 of FIG. 1, multilayer filter PCB 200 of FIG. 2, multilayer filter PCB 300 of FIGS. 3A and 3B or multilayer filter 400 of FIGS. 4A and 4B.

To ensure that multilayer filter PCB 501 fits securely inside cylindrical body 502 it may be advantageous to vary the width and length of multilayer filter PCB 501. Other filtering structures (e.g., wires and electrically conductive traces, not shown in FIG. 5) may be present in tubular filter structure 503 and may be comprised of material that is superconducting. Tubular filter structure 503 is herein described as having a cylindrical geometry; however, a person skilled in the art will understand that the description and the appended claims are not limited to a specific geometry and other geometries, such as rectangular prisms or tube with hexagonal cross sections, may be used. Example of tubular filter structures and filtering elements are described in more details in U.S. Pat. Nos. 8,279,022, 8,346,325.

FIG. 6A is a planar view 600a of an exemplary inner layer 601a in a multilayer printed circuit board where filtering material is disposed in a pattern. A filtering material 602a through 602n (collectively 602, here represented by shaded squares) is disposed within inner layer 601a in a regular, repeating, pattern, specifically a checkerboard pattern, interspersed with electrically insulative material. A person skilled in the art will understand that the size and number of filtering material 602 may vary in different implementation of inner layer 601a. Filtering material 602 may comprise superconducting material, normal material, a combination of superconducting and normal material, a ground plane, a magnetic material, or a semi-conductor material. In some implementations, filtering material 602 may be metal powder or metal strands. In some implementations, filtering material 602 comprises more than one type of filtering material (e.g., filtering material 602a may be a superconducting material and filtering material 602n may be a semi-conductor material). Inner layer 601a may be used as any of the inner layer 103 of FIG. 1, inner layer 203, third layer 204 or fourth layer 205 of FIG. 2, first inner layer 303 or second inner layer 304 of FIGS. 3A and 3B, and first inner layer portion 403 and second inner layer portion 404 of FIGS. 4A and 4B.

FIG. 6B is a planar view 600b of an exemplary inner layer 601b in a multilayer printed circuit board where filtering material is disposed randomly. A filtering material 603 (represented by strands of different lengths, only one called out in FIG. 6B to reduce clutter) is disposed within inner layer 601b in random order, interspersed with electrically insulative material. Filtering material 603 may comprise superconducting material, normal material, a combination of superconducting and normal material, a ground plane, a magnetic material, or a semi-conductor material. In some implementations, filtering material 603 may be metal powder or metal strands. A person skilled in the art will understand that the size and amount of filtering material 603 may vary in different implementations of inner layer 601b. A person skilled in the art will understand that filtering material 603 may comprise one or more different types of filtering material disposed at random within inner layer 601b (e.g., a superconducting material and a semi-conductor material). Filtering material 603 is electrically isolated, i.e., there is no electrical connection between separate strands of filtering material. Inner layer 601b may be used as any of the inner layer 103 and 203 of FIGS. 1 and 2, respectively, of third layer 204 or fourth layer 205 of FIG. 2, of first inner layer 303 or second inner layer 304 of FIGS. 3A and 3B, and first inner layer portion 403 and second inner layer portion 404 of FIGS. 4A and 4B.

FIG. 6C is a planar view 600c of an exemplary inner layer 601c in a multilayer printed circuit board where filtering material consists of electrical pathways. Electrical wires 604a through 604g (collectively, 604) extend along the length 605 of inner layer 601c. A person skilled in the art will understand that the number of electrical wires 604 may vary in different implementations of inner layer 601c. Electrical wires 604 are electrically isolated from each other. Inner layer 601c may be used as any of the inner layer 103 and 203 of FIGS. 1 and 2, respectively, of third layer 204 or fourth layer 205 of FIG. 2, of first inner layer 303 or second inner layer 304 of FIGS. 3A and 3B, and first inner layer 403 and second inner layer 404 of FIGS. 4A and 4B.

FIG. 6D is a planar view 600d of an exemplary inner layer 601d in a multilayer printed circuit board where filtering material consists of electrical pathways in a meander pattern. Lengths of electrical wires 604a through 604g (collectively 604) extend along the length 605 of inner layer 601d and are electrically connected at alternate ends through lengths of electrical wire 606a though 606f (collectively, 606). A person skilled in the art will understand that the number and span of lengths of electrical wires 604 and 606 may vary in different implementations of inner layer 601d. Inner layer 601d may be used as any of the inner layer 103 and 203 of FIGS. 1 and 2, respectively, of third layer 204 or fourth layer 205 of FIG. 2, of first inner layer 303 or second inner layer 304 of FIGS. 3A and 3B, and first inner layer portion 403 and second inner layer portion 404 of FIGS. 4A and 4B.

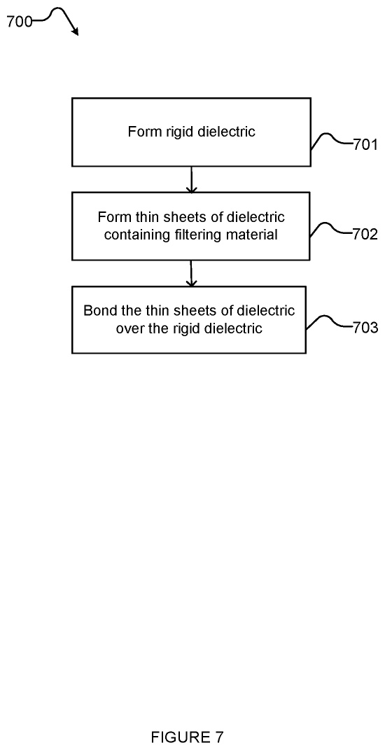

FIG. 7 is a flow chart of an exemplary method 700 for assembling a multiplayer filter PCB, as described in FIGS. 1, 2, 3A and 3B, 4A and 4B. Method 700 comprises acts 701 through 703, however, a person skilled in the art will understand that that the number of acts is exemplary and, in some implementations, certain acts may be omitted, further acts may be added, and/or the order of the acts may be changed.

Method 700 may be used as part of a process to assemble tubular filters, for example tubular filer structures described in U.S. Pat. Nos. 8,441,329 and 8,279,022.

At 701 a rigid dielectric layer is formed. The rigid dielectric can be, for example an FR4. Standard methods for forming a rigid dielectric layer may be used at 701. Optionally, at 701, filtering material may be deposited into the rigid dielectric during the assembly, for example before curing. The filtering material may be deposited in a pattern or randomly as described in FIGS. 6A, 6B and 6C. The pattern may, for example, be a repeating pattern. In at least one implementation the filtering material may comprise superconducting material, normal material, a combination of superconducting and normal material, a ground plane, a magnetic material, or a semi-conductor material. In some implementations, the filtering material may be metal powder or metal strands.

At 702 at least one thin sheet of dielectric containing filtering material is formed. The at least one thin sheet of dielectric may be forming at least one of the inner layers described in FIGS. 1, 2 and 3A and 3B, 4A and 4B. Filtering material is added to the least one thin sheet of dielectric. The filtering material may be deposited on the at least one thin sheet of dielectric in a pattern or randomly, as described in FIGS. 6A, 6B and 6C. In at least one implementation the filtering material may comprise superconducting material, normal material, a combination of superconducting and normal material, a ground plane, a magnetic material, or a semi-conductor material. In some implementations, the filtering material may be metal powder or metal strands.

At 703, the at least one thin sheet of dielectric containing filtering material is bonded (e.g., laminated) together with the rigid dielectric layer to form a multilayer filter PCB. Additionally, one or more rigid dielectric layers can be bonded over the at least one thin sheet of dielectric layer, as shown in FIGS. 1, 2, 3A and 3B, 4A and 4B. The at least one implementation the at least one thin sheet of dielectric is deposited over the rigid dielectric layer via spray coating, electroplating, electro-less plating, evaporation, silkscreen, plasma, sputtering, mechanical spreading, thick-coat, hot or cold rolling, sintering, molding, casting, or photo lithography.

The above described method(s), process(es), or technique(s) may include various acts, though those of skill in the art will appreciate that in alternative examples certain acts may be omitted and/or additional acts may be added. Those of skill in the art will appreciate that the illustrated order of the acts is shown for exemplary purposes only and may change in alternative examples. Some of the exemplary acts or operations of the above described method(s), process(es), or technique(s) are performed iteratively. Some acts of the above described method(s), process(es), or technique(s) can be performed during each iteration, after a plurality of iterations, or at the end of all the iterations.

The above description of illustrated implementations, including what is described in the Abstract, is not intended to be exhaustive or to limit the implementations to the precise forms disclosed. Although specific implementations of and examples are described herein for illustrative purposes, various equivalent modifications can be made without departing from the spirit and scope of the disclosure, as will be recognized by those skilled in the relevant art.

The various implementations described above can be combined to provide further implementations. All of the commonly assigned US patent application publications, US patent applications, foreign patents, and foreign patent applications referred to in this specification and/or listed in the Application Data Sheet are incorporated herein by reference, in their entirety, including but not limited to: U.S. Provisional Patent Application No. 62/733,184; U.S. Pat. Nos. 8,279,022; 8,346,325; 8,441,329; 8,008,991; 8,159,313; 8,315,678; and International Patent Application No. US2017/65152.

These and other changes can be made to the implementations in light of the above-detailed description. In general, in the following claims, the terms used should not be construed to limit the claims to the specific implementations disclosed in the specification and the claims, but should be construed to include all possible implementations along with the full scope of equivalents to which such claims are entitled. Accordingly, the claims are not limited by the disclosure.

1. A multilayer printed circuit board comprising:
a first electrically insulative layer;
a second electrically insulative layer; and
a first filter layer sandwiched between the first and the second electrically insulative layers, the first filter layer comprising a first electrically conductive filter material dispersed therein and, or thereon.

2. The multilayer printed circuit board of claim 0 wherein the first electrically conductive filter material comprises at least one of: a superconductive material, a superconducting powder, a normal metal, a superconductive material and a normal material, a ground plane, a magnetic material and a semiconductor material.

3. The multilayer printed circuit board of claim 0 wherein at least one of the first electrically insulative layer and the second electrically insulative layer is an FR4 layer.

4. The multilayer printed circuit board of claim 0 further comprising:
a second filter layer sandwiched between the first filter layer and the second electrically insulative later, the second filter layer comprising a second electrically conductive filter material dispersed therein and, or thereon.

5. The multilayer printed circuit board of claim 0 further comprising a second filter layer and a third filter layer, wherein the first electrically insulative layer is sandwiched between the first filter layer and the second filter layer and the second insulative layer is sandwiched between the first filter layer and the third filter layer, and the second filter layer comprises a second electrically conductive filter material dispersed therein and, or thereon, and the third filter layer comprises a third electrically conductive filter material dispersed therein and, or thereon.

6. The multilayer printed circuit board of claim 0 wherein the first electrically conductive filter material is the same as the second and the third electrically conductive filter material.

7. The multilayer printed circuit board of claim 0 wherein the first filter layer comprises a first portion and a second portion wherein the first and second portions are co-planar with the first filter layer and wherein the first portion comprises the first electrically conductive filter material dispersed therein and, or thereon and the second portion comprises a second electrically conductive filter material dispersed therein and, or thereon.

8. The multilayer printed circuit board of claim 0 wherein the first electrically conductive filter material and the second electrically conductive filter material are distributed in a pattern on the first filter layer.

9. The multilayer printed circuit board of claim 0 wherein the first and second electrically conductive filter material are electrically coupled together.

10. The multilayer printed circuit board of claim 0 wherein the first and second electrically conductive filter material are electrically isolated from each other.

11. A method for assembling a multilayer printed circuit board, the method comprising:
forming a first electrically insulative layer;
forming a second electrically insulative layer;
forming a first filter layer, the first filter layer having a first electrically conductive filter material dispersed therein and, or thereon; and
bonding the first filter layer between the first and the second electrically insulative layers.

12. The method of claim 0 wherein forming a first filter layer, the first filter layer having a first electrically conductive filter material dispersed therein and or, thereon includes forming an first filter layer, the first filter layer having one of: a superconductive material, a superconducting metal powder, a normal metal, a superconductive material and a normal material, a ground plane, a magnetic material and a semiconductor material, dispersed therein and, or thereon.

13. The method of claim 0 wherein forming a first electrically insulative layer includes forming an FR4 layer and forming a second electrically insulative layer includes forming an FR4 layer.

14. The method of claim 0 further comprising forming a second filter layer sandwiched between the first filter layer and the second electrically insulative layer, the second filter layer comprising a second electrically conductive filter material dispersed therein and, or thereon.

15. The method of claim 0 further comprising forming a second filter layer and a third filter layer, the first electrically insulative layer sandwiched between the first filter layer and the second filter layer and the second electrically insulative layer sandwiched between the first filter layer and the third filter layer, the second filter layer comprising a second electrically conductive filter material dispersed therein and, or thereon and the third filter layer comprising a third electrically conductive filter material dispersed therein and, or thereon.

16. The method of claim 0 wherein forming a second filter layer and a third filter layer, the second filter layer comprising a second electrically conductive filter material dispersed therein and, or thereon and the third filter layer comprising a third electrically conductive filter material dispersed therein and, or thereon includes forming a second filter layer and a third filter layer, the second filter layer comprising a second electrically conductive filter material dispersed therein and, or thereon and the third filter layer comprising a third electrically conductive filter material dispersed therein and, or thereon, the second electrically conductive filter material the same as the third and the first electrically conductive filter material.

17. The method of claim 0 wherein forming a first filter layer includes forming a first portion and a second portion, the first and second portions co-planar with the first filter layer, the first portion containing the first electrically conductive filter material dispersed therein and, or thereon, and the second portion containing a second electrically conductive filter material dispersed therein and, or thereon.

18. The method of claim 0 wherein forming a first portion and a second portion, the first portion containing the first electrically conductive filter material dispersed therein and, or thereon, and the second portion containing a second electrically conductive filter material dispersed therein and, or thereon includes forming a first portion and a second portion, the first and second portion distributed in a pattern on the first filter layer, the first portion containing the first electrically conductive filter material dispersed therein and, or thereon, and the second portion containing the second electrically conductive filter material dispersed therein and, or thereon.

19. The method of claim 0 wherein forming a first portion and a second portion, the first portion containing the first electrically conductive filter material dispersed therein and, or thereon, and the second portion containing a second electrically conductive filter material dispersed therein and, or thereon includes forming first portion and a second portion, the first portion containing the first electrically conductive filter material dispersed therein and, or thereon, the second portion containing the second electrically conductive filter material dispersed therein and, or thereon, and the first and second electrically conductive material electrically coupled together.

20. The method of claim 0 wherein forming a first portion and a second portion, the first portion containing the first electrically conductive filter material dispersed therein and, or thereon, and the second portion containing a second electrically conductive filter material dispersed therein and, or thereon includes forming a first portion and a second portion, the first portion containing the first electrically conductive filter material dispersed therein and, or thereon, the second portion containing the second electrically conductive filter material dispersed therein and, or thereon, and the first and second electrically conductive material electrically isolated.
